(19) United States
(12) Patent Application Publication
(10) Pub. No.: US 2025/0151303 A1
(43) Pub. Date: May 8, 2025

(54) METHOD FOR PRODUCING A MICROELECTRONIC DEVICE BASED ON A SEMI-METALLIC MATERIAL

(71) Applicant: COMMISSARIAT A L'ENERGIE ATOMIQUE ET AUX ENERGIES ALTERNATIVES, Paris (FR)

(72) Inventor: Sylvain BARRAUD, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/799,675

(22) Filed: Aug. 9, 2024

(30) Foreign Application Priority Data
Aug. 11, 2023 (FR) 2308687

(51) Int. Cl. H10D 30/01; H10D 30/00

(52) U.S. Cl. CPC H10D 30/0191; H10D 30/502

(57) ABSTRACT

The invention relates to a device comprising a transistor (T1, T2) comprising:
a source (42) and a drain (43),
a plurality of channels (41a, 41b, 41c) based on a semi-metallic material,
a gate-all-around (50) surrounding the channels (41a, 41b, 41c),
a gate dielectric layer (30) separating each channel (41a, 41b, 41c) and the gate-all-around (50),
source and drain contacts (40S, 40D) based on the semi-metallic material,

Advantageously, the gate-all-around (50) totally surrounds one or more of the channels (41a, 41b, 41c), according to a GAA architecture.

The invention also relates to a method for producing such a device.

### TECHNICAL FIELD

The present invention relates to the field of microelectronics technologies. It has a particularly advantageous application in manufacturing advanced FET (Field-Effect Transistor)-type devices, the conduction channels of which are based on a semi-metallic material.

### PRIOR ART

To respond to the increasing requirements on performance of microelectronic devices and their miniaturisation, using materials other than silicon is now considered for manufacturing transistors. An example of materials integrated recently in transistors is bismuth, a semi-metallic material. In the solid state, a semi-metallic material has electric properties similar to those of a metallic material. However, when the semi-metallic material is structured so as to have nanometric dimensions, this material adopts an electric behaviour similar to that of a semiconductor. This is, in particular, due to a quantum confinement effect.

The document, “Semimetal to semiconductor transition and polymer electrolyte gate modulation in single-crystalline bismuth nanowires, Jeongmin Kim and Wooyoung Lee, Nanoscale, 2 (2017)” discloses a bismuth nanowire-based device. In this method, the bismuth nanowires are initially synthesised on a bismuth substrate, then detached from their support and manipulated individually in view of designing channels of a field-effect transistor. Although this device demonstrates promising performance, its manufacturing method does not enable its industrialisation nor its large-scale production.

Document US2018/0190799 A1 discloses another manufacturing method integrating a semi-metallic material in a gate-all-around transistor. A vertical arrangement of the channels is disclosed in this document. A bismuth-based semi-metallic layer is deposited in holes having nanometric dimensions to form the semiconductor channels in the form of vertical nanowires. The semi-metallic layer opens into holes to form source or drain regions. These source/drain regions have dimensions larger than those of the channels, and have a metallic character. Such a method utilising the semimetal/semiconductor transition by geometric constriction is adapted to an industrial use. Forming holes having nanometric dimensions is difficult to control. The integration densities accessible by this method remain limited.

Document FR3095549 discloses another method for producing a transistor based on a semi-metallic material according to a planar arrangement. The production of such an architecture is simpler and more reliable. A “mould” defining the patterns intended to form the channels and the source and drain regions and their contacts, is, in this case, produced beforehand. The semi-metallic material is then deposited in this mould, then thinned by polishing. This makes it possible to more easily obtain dimensions giving a semiconductor character to the channels. There again, the integration density remains limited. The electrostatic control of the transistors is also limited.

The present invention proposes to overcome, at least partially, the disadvantages of known methods and architectures. In particular, an aim of the present invention is to propose a device making it possible to increase the integration density of transistors based on a semi-metallic material. Another aim of the present invention is to propose a method for manufacturing such a device.

### SUMMARY

To achieve this aim, according to an embodiment, a microelectronic device is provided, comprising at least one transistor comprising:
a source and a drain,
a plurality of channels based on a semi-metallic material, said channels extending along a longitudinal direction x between the source and the drain, each channel having at least one transverse dimension, taken perpendicularly to the longitudinal direction x, such that the semi-metallic material has an electric conduction property of a semiconductor material,
a so-called gate-all-around, surrounding at least one of the channels, and preferably several channels of the plurality of channels,
a gate dielectric layer separating each channel and the gate-all-around,
source and drain contacts connected respectively to the source and to the drain, at least one from among the source and drain contacts being based on the semi-metallic material and having dimensions such that the semi-metallic material has an electric conduction property of a metallic material,
spacers on either side of the gate, configured to electrically isolate the gate with respect to the source and drain contacts.

Advantageously, the gate-all-around totally surrounds at least one of the channels, and preferably several channels of the plurality of channels, in a transverse plane yz perpendicular to the longitudinal direction x.

Such a gate-all-around architecture is called GAA, and comprises channels stacked on one another along a so-called vertical direction z, surrounding by a common gate. This advantageously makes it possible to improve the electrostatic control of transistors and to obtain a higher current density per surface unit. Moreover, such an architecture enables a high integration density of transistors. In particular, the device can comprise at least two adjacent transistors along a horizontal direction, each transistor comprising channels stacked along the vertical direction z.

Such a device architecture advantageously exceeds the performance of known transistor architectures based on a semi-metallic material.

Another aspect of the invention relates to a method for manufacturing such a microelectronic device, comprising the following steps:
Providing, on a substrate, a stack comprising, along the direction z, a plurality of first layers made of a first material, alternated with a plurality of second layers made of a second material, the first material and the second material being different from one another and different from the semi-metallic material forming the channels,
Forming, in this stack, first openings defining first patterns,
Forming a sacrificial gate mounted on the first patterns and partially in the first openings,
Forming, in the first patterns, second openings defining second patterns, such that the second patterns are transverse to the first patterns,
Forming the gate dielectric layer,
Forming the spacers,
Forming a holding layer in said second openings on exposed flanks of the second patterns,
Removing the sacrificial gate so as to form third openings,
Removing totally, from the third openings, the first material of the first layers selectively at the second material from the second layers, so as to form cavities,
Filling the cavities with a gate material, so as to form the gate-all-around,
Removing at least partially the holding layer so as to reform at least partially the second openings exposing flanks of the second layers,
Removing totally, from the second openings, the second material from the second layers so as to form second spaces,
Depositing a layer based on a semi-metallic material in the second spaces and at least partially in the second openings, so as to form simultaneously:
   channels based on the semi-metallic material in vertical alignment with the gate-all-around,
   at least one from among the source and drain contacts based on the semi-metallic material.

A principle of the method according to the invention consists of selectively replacing certain layers of the initial stack with the semi-metallic material in order to form the channels of the transistor. Depositing the semi-metallic material advantageously forms, in one single step, the channels and at least one of the drain or source contacts. The initial stack does not comprise the semi-metallic material. The subsequent deposition of the semi-metallic material aims to best preserve the semi-metallic material.

Thus, the semi-metallic material layers are introduced at the end of the method, after structuration of the stack and typically after the formation of the spacers and of the gate-all-around. This advantageously makes it possible to limit the risk of degradation of the semi-metallic material during the method. The semi-metallic material is not exposed to all the steps of the manufacturing method. The semi-metallic material is thus preserved.

Furthermore, the late introduction of the semi-metallic material during the manufacturing method makes it possible to use standard microelectronics technologies for the formation and the structuration of the stack. It is not necessary to modify or to adapt the standard structuration technological steps to the limitations of use of the semi-metallic material. The costs of the method are thus advantageously limited. The method can further be more easily implemented in current production lines.

Other aims, features and advantages of the present invention will appear upon examining the following description and the accompanying drawings. It is understood that other advantages can be incorporated.

### BRIEF DESCRIPTION OF THE FIGURES

FIGS. 1A, 2A, 3A, 4A, 5A, 6A, 7A, 8A, 9A, 10A, 11A, 12A, 13A, 14A, and 15A schematically illustrate, along the cross-sections xz of the steps of manufacturing a GAA transistor device, according to a first embodiment of the present invention.

FIGS. 1B, 2B, 3B, 4B, 5B, 6B, 7B, 8B, 9B, 10B, 11B, 12B, 13B, 14B, and 15B schematically illustrate, along the cross-sections yz indicated in the corresponding figures nA, the same steps of manufacturing the device as those represented in FIGS. 1A-15A, respectively.

FIG. 14C illustrates a variant of an embodiment regarding the shape of the channels of the transistors of the device according to the invention.

FIGS. 16A, 17A, 18A, 19A, and 20A schematically illustrate, along the cross-sections xz of the steps of manufacturing a GAA transistor device, according to a second embodiment of the present invention.

FIGS. 16B, 17B, 18B, 19B, and 20B schematically illustrate, along the cross-sections yz indicated in the corresponding figures nA, the same steps of manufacturing the device as those represented in FIGS. 16A-20A, respectively.

In the figures in cross-sections, cutting planes are indicated (A-A′, B-B′, . . . , T-T′) with crossed references to the cutting planes of the corresponding figures. The drawings are given as examples and are not limiting of the invention. They constitute principle schematic representations intended to facilitate the understanding of the invention and are not necessarily to the scale of practical applications. In particular, in the principle diagrams, the thicknesses and/or the dimensions of the different layers, patterns and raised elements are not representative of reality. For reasons of clarity, all of the alphanumeric references are not systematically repeated from one figure to another. It is understood that the elements already described and referenced when they are reproduced in another figure typically have the same alphanumeric references, even if these are not explicitly mentioned. A person skilled in the art will identify, without difficulty, one same element reproduced in different figures.

### DETAILED DESCRIPTION

Before starting a detailed review of embodiments of the invention, optional features are stated below, which can optionally be used in association or alternatively:

According to an example, the device comprises at least two transistors disposed along a so-called horizontal first direction x or y, and the channels of each transistor are stacked along a so-called vertical second direction z, perpendicular to the first direction x or y.

According to an example, one from among the source and drain contacts is based on the semi-metallic material and the other from among the source and drain contacts is based on a metal.

According to an example, the semi-metallic material is based on at least one element from among bismuth (Bi), tin (Sn), antimony (Sb), arsenic (As).

According to an example, the formation of the spacers comprises the following steps:
Forming first spacers bordering the sacrificial gate and bearing on the first patterns,
Before the formation of the holding layer, removing partially, from the second openings, the first material of the first layers selectively at the second material of the second layers, so as to form first spaces in vertical alignment with the first spacers,
Filling the first spaces with a first dielectric material to form internal spacers.

According to an example, the first patterns extend mainly along the longitudinal direction x, and the second patterns extend mainly along a transverse direction y.

According to an example, the gate-all-around is formed before the deposition of the layer based on the semi-metallic material. This corresponds to a “gate first”-type method (the replacement of the sacrificial gate with a functional gate is done before the formation of the channels of the transistors).

According to an example, the formation of the gate dielectric layer is formed after total removal of the first material of the first layers and before formation of the gate-all-around, by deposition of a dielectric layer in the cavities and in the third openings, on the exposed parts of the second layers.

According to an example, the formation of the spacers and the formation of the gate dielectric layer are done at least partially by one same deposition of a dielectric layer in the cavities. This makes it possible to reduce the number of steps of the method and/or reduce the thickness of the spacers.

According to an example, the deposition of the layer based on the semi-metallic material is done in the second spaces and in all the second openings, so as to form the channels and all the source and drain contacts. The number of steps of the method is advantageously reduced.

According to an example, the method further comprises, after deposition of the layer based on the semi-metallic material, a crystallisation annealing.

According to an example, the layer based on the semi-metallic material is covered prior to the crystallisation annealing, and the crystallisation annealing is done at a temperature greater than the melting point of the semi-metallic material.

According to an example, the second openings are reformed by successively exposing one single flank of the second layers, and the deposition of the layer based on the semi-metallic material forms one single contact from among the source and drain contacts.

According to an example, the other contact from among the source and drain contacts is a metallic contact formed by deposition of a metallic layer in a part of the second openings.

According to an example, the deposition of the layer based on the semi-metallic material is done by growth, preferably by epitaxy, from exposed zones of said metallic contact through second spaces.

The invention generally relates to a method for manufacturing a GAA transistor microelectronic device, based on a semi-metallic material. Such a microelectronic device can have a “GAA stacked nanosheet”-type architecture. A stacked nanowire and gate-all-around architecture is also possible.

The nanowires or nanosheets typically each comprise a conduction channel of a transistor. These channels are stacked along a direction z. This means that they each occupy a given altitude level along the direction z. A level can be defined between two planes perpendicular to the direction z.

Advantageously, the method according to the invention can be implemented to produce MOS GAA transistors for 5 nm and sub-5 nm technological nodes.

A microelectronic device comprising GAA transistors can advantageously be integrated in logic systems having 3D architectures. These transistors can, in particular, be associated with other structural or functional elements so as to design complex systems.

A particular aspect of the invention relates to the implementation of semi-metallic material to produce the nanowires or nanosheets of the device. These semi-metallic materials can have properties of a metal or of a semiconductor, typically according to the temperature or of a dimensional confinement. The band structure of the semi-metallic or semimetal materials moves them closer from the metals, insofar as these materials have no bandgap, but the low density of electronic states at the Fermi level splits the carriers into two populations, electrons and holes, like for the semiconductors. Thus, it is possible to act on the type of electric conduction of the semi-metallic materials, by modifying their dimensions. When the dimensions of a semimetal are reduced, the concentration of the carriers is first almost constant, like in the metals, then increases substantially by quantum confinement, like in the semiconductors. Thus, a semimetal-semiconductor transition is observed. Bismuth can behave like a semiconductor when it is deposited in thin layers of thickness less than a critical value of 30 nm.

In the scope of the present invention, the semi-metallic materials are preferably bismuth (Bi)-, tin (Sn)-, antimony (Sb)-, arsenic (As)-, tellurium (Te)-based. Other materials having semi-metallic properties, at least under certain conditions, can also be considered. Certain alloys can be semi-metallic, like mercury telluride HgTe. Certain conductive polymers can have semi-metallic phases; certain thin-layer graphene structures, for example, can be semi-metallic according to their magnetic environment.

It is specified that, in the scope of the present invention, the terms “on”, “surmounts”, “covers”, “underlying”, “opposite” and their equivalents do not necessarily mean “in contact with”. Thus, for example, the deposition or the application of a first layer on a second layer, does not compulsorily mean that the two layers are directly in contact with one another, but means that the first layer covers at least partially the second layer by being either directly in contact with it, or by being separated from it by at least one other layer or at least one other element.

By a substrate, a film, a layer “based on” a material A, or A-based, this means a substrate, a film, a layer comprising this material A only or this material A, and optionally other materials, for example, doping elements or alloy elements. Thus, a silicon nitride SiN-based spacer can, for example, comprise non-stoichiometric silicon nitride (SiN), or stoichiometric silicon nitride (Si3N4), or also a silicon oxynitride (SiON).

The word “dielectric” qualifies a material of which the electric conductivity is sufficiently low in the given application to serve as an isolator. In the present invention, a dielectric material preferably has a dielectric constant of less than 20.

Several embodiments of the invention implementing successive steps of the manufacturing method are described below. Unless explicitly mentioned, the adjective “successive” does not necessarily imply, even if this is generally preferred, that the steps follow one another immediately, intermediate steps being able to separate them.

Moreover, the term “step” means the performing of a part of the method, and can mean a set of substeps.

Moreover, the term “step” does not compulsorily mean that the actions carried out during a step are simultaneous or immediately successive. Certain actions of a first step can, in particular, be followed by actions linked to a different step, and other actions of the first step can then be repeated. Thus, the term “step” does not necessarily mean single and inseparable actions over time and in the sequence of the phases of the method.

By “selective etching with respect to” or “etching having a selectivity with respect to” means an etching configured to remove a material A or a layer A with respect to a material B or a layer B, and having an etching speed of the material A greater than the etching speed of the material B. The selectivity is the ratio between the etching speed of the material A over the etching speed of the material B. It is referenced S_{A:B}. A selectivity S_{A:B} of 10:1 means that the etching speed of the material A is 10 times greater than the etching speed of the material B.

The different patterns formed during the manufacturing steps typically have a structure intended to evolve during the steps of the method. Thus, the patterns can comprise the sacrificial layers of the initial stack, the semi-metallic material-based layers, the dielectric layers, continuous or discontinuous. The different patterns aim to form, at the end of the method, “transistor patterns”, each comprising at least one conduction channel and one gate surrounding said channel, a dielectric barrier separating the gate and the channel, a source and a drain on either side of the channel. The congregation of the first and second layers in the initial stack can be inverted.

A preferably orthonormal system, comprising the axes x, y, z is represented in the accompanying figures.

In the present patent application, thickness will preferably be referred to for a layer or a film, and height will preferably be referred to for a device or a structure. The thickness is taken along a direction normal to the main extension plane of the layer or of the film. Thus, a superficial silicon layer (topSi) typically has a thickness along z. A gate pattern formed on such a superficial layer has a height along z. The relative terms “on”, “surmounts”, “under”, “underlying” refer to positions taken along the direction z. A “lateral” dimension corresponds to a dimension along a direction of the plane xy. By a “lateral” extension or “laterally”, this means an extension along one or more directions of the plane xy.

In the present patent application, the longitudinal direction corresponds to the direction along which the channel of a transistor extends, between the source and the drain. The longitudinal direction is directed along x in the illustrated figures. A transverse direction is directed along y or z. A transverse dimension is typically taken along y or z. The thickness of the layer forming the channel is a transverse dimension of the channel.

An element located “in vertical alignment with” or “to the right of” another element means that these two elements are both located on one same line perpendicular to a plane, in which a lower or upper face of a substrate mainly extends, i.e. on one same line oriented vertically in the figures as a cross-section.

The terms “substantially”, “about”, “around” mean plus or minus 10%, and preferably plus or minus 5%. Moreover, the terms “between . . . and . . . ” and equivalents mean that the limits are inclusive, unless mentioned otherwise.

The description below has an example of an implementation of the method according to the invention in a context of developing a complex 3D device. The scope of this description is clearly not limiting of the invention.

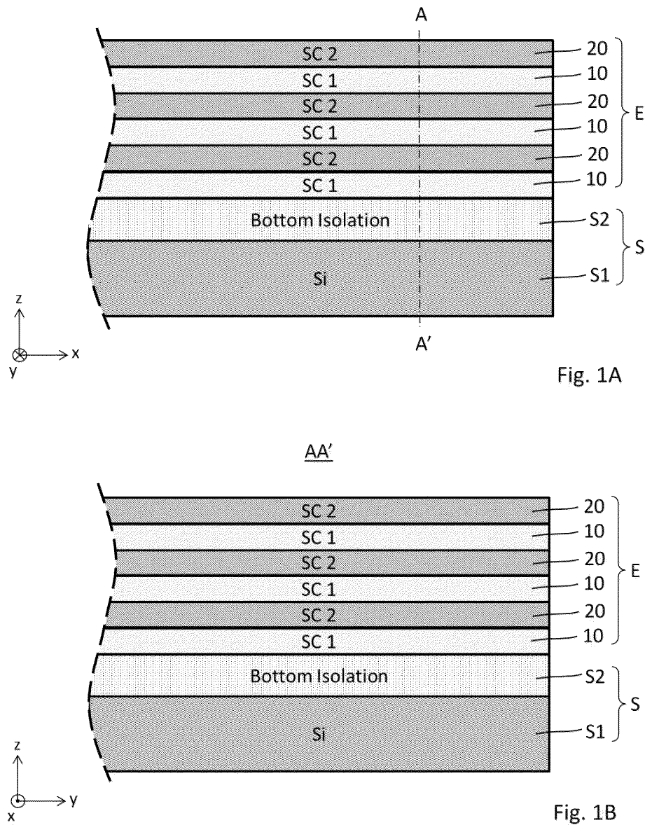

FIGS. 1A, 1B to 15A, 15B schematically illustrate steps of manufacturing a device comprising GAA transistors based on a semi-metallic material, according to a first embodiment. Figures nA (n=1 . . . 15) correspond to first cross-sections along a plane xz, each illustrating a different step of the manufacturing method. Figures nB (n=1 . . . 15) correspond to second cross-sections along a plane yz, each illustrating the same step as the corresponding figure nA.

As illustrated in FIGS. 1A, 1B, a first step consists of producing a stack E of semiconductive layers 10, 20 on a substrate S. The substrate S can be an SOI (Silicon On Insulator)-, GeOI (Germanium On Insulator)- or SGOI (Silicon-Germanium On Insulator)-type substrate. These substrates are grouped together, called “semiconductor-on-insulator”. These known substrates comprise, according to current terminology for a person skilled in the art, a so-called “Si bulk” thick silicon support layer S1, a so-called “BOX” (Buried Oxide) silicon oxide isolating layer S2, and a superficial thin layer, respectively silicon-, germanium- or silicon-germanium-based. This superficial thin layer can advantageously correspond to the first layer 10 of the stack E. In this case, the final device comprising GAA transistors based on a semi-metallic material rests on the isolating layer (BOX) of the semiconductor-on-insulator-type substrate.

Alternatively, the substrate S can be an “Si bulk” solid substrate.

The stack E comprises, according to an example, an alternance of first silicon-germanium (SiGe) layers 10 and of second silicon (Si) layers 20.

The concentration of Ge in the SiGe alloy can be of 20%, 30% or 45%, for example. This concentration of germanium is chosen so as to enable a good selectivity of the etching of SiGe with respect to Si, during selective etching steps. The greater the concentration of Ge will be, the greater the Si selectivity during the subsequent removal of SiGe will be. This stack E is advantageously formed by epitaxy of the SiGe 10 and Si 20 layers. This step of forming the stack E is inexpensive and well-known to a person skilled in the art. The thicknesses of the Si and SiGe layers can be between 5 nm and 20 nm, and preferably between 4 nm and 10 nm. In a known manner, in order to avoid the formation of structural defects, the maximum thicknesses permitted for the SiGe layers 10 depend in particular on the concentration of Ge chosen.

In the example illustrated in FIGS. 1A, 1B, three SiGe layers 10 are alternated with three epitaxially grown Si layers 20. A super Si/SiGe array is thus obtained. The number of Si and SiGe layers can naturally be increased. This ultimately makes it possible to increase the number of channels stacked per transistor in the final device.

Generally, the first material of the first layers 10 and the second material of the second layers 20 are chosen, such that one can be etched selectively with respect to the other. Thus, other pairs of first and second materials are possible. By respecting this condition of selectivity to the etching, the first and second materials can be chosen from among dielectric materials (oxides and nitrides, for example), semiconductor materials, metallic materials.

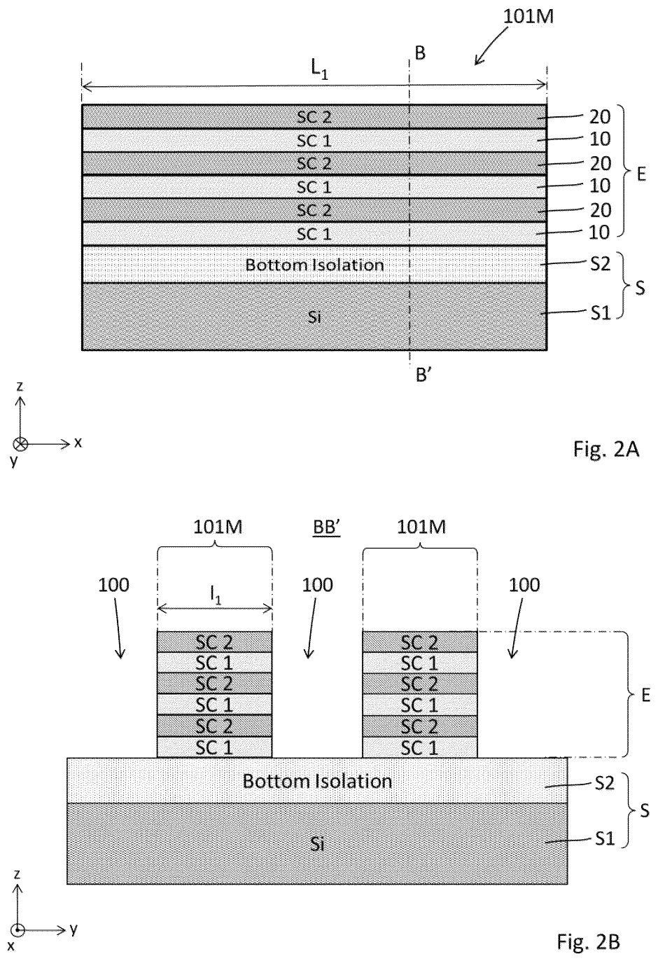

As illustrated in FIGS. 2A, 2B, a conventional lithography/etching step is carried out in order to define first patterns 101M, and first openings 100. The etching is anisotropic and directed along z. It is configured to etch the stack E, in this case, the super Si/SiGe array, over its entire height, by stopping on the substrate S, in this case the BOX S2. It can be done by plasma by using an HBr/O2 etching chemistry. The first patterns 101M can have a length L₁ along x of between 10 nm and 500 nm. They preferably have a width I₁ along y of between 5 nm and 20 nm. This first structuration of the stack E in the form of fins, makes it possible define a plurality of superposed nanowires or nanosheets.

For clarity, the following figures iB (i=3 . . . 15) only illustrate one single “fin” pattern 101M.

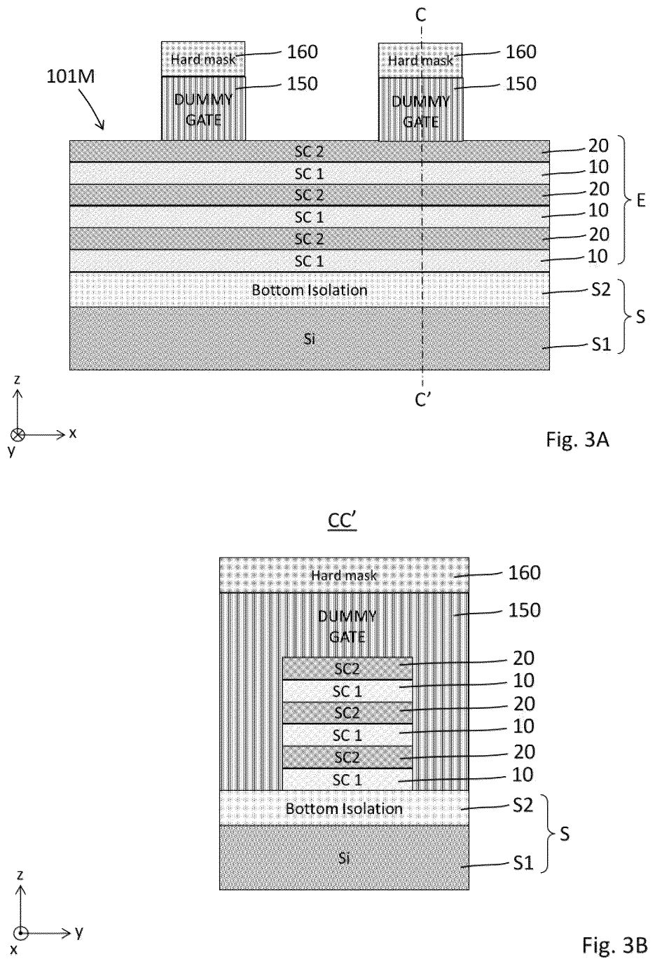

As illustrated in FIGS. 3A, 3B, sacrificial gates 150 are then formed on the “fin” patterns 101M. The formation of these sacrificial gates 150 is done typically by deposition then lithography/etching. The formation of the sacrificial gates 150 is configured such that the sacrificial gates 150 are mounted on the “fin” patterns 101M, as illustrated in FIG. 3B. The sacrificial gates 150 typically comprise an upper part located on the “fin” pattern 101M, and lateral parts located on the lateral flanks of the “fin” pattern 101M. The sacrificial gates 150 typically bear on the substrate S. At this stage, the sacrificial gates 150 are typically surmounted by an etching mask 160, called hard mask, implemented in the structuration of the sacrificial gates 150. The sacrificial gates 150 are, for example, polycrystalline silicon-based. A thin oxide layer SiO₂, of 7 nm thickness for example, is preferably deposited prior to the formation of the sacrificial gates 150. This thin oxide layer SiO₂ (not illustrated in the figures) is thus inserted between the sacrificial gates 150 and the “fin” patterns 101M. This thin oxide layer SiO₂ can form a stop layer for the subsequent etching of the sacrificial gates 150.

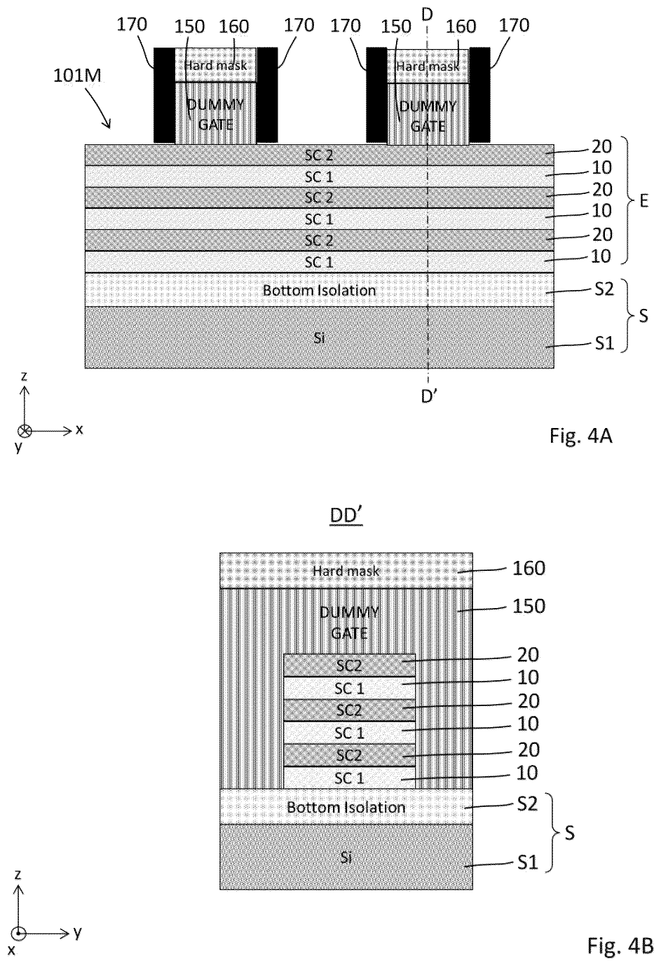

As illustrated in FIGS. 4A, 4B, first spacers 170 are then formed on the flanks oriented along yz of the sacrificial gates 150. Generally, projecting along z, these spacers form a continuous ring around each sacrificial gate 150, with a closed contour. In a cross-section, however, along the plane xz illustrated in FIG. 4A, the first spacer 170 has two parts opposite one another on each of the flanks of the sacrificial gate 150. These two parts are generally designated as being the first spacers 170, even if these can be considered as belonging to one single and same spacer. The first spacers 170 typically extend up to an upper face of the hard masks 160. The first spacers 170 are typically silicon nitride SiN-based or based on a dielectric material with low dielectric constant, for example, SiCO-based.

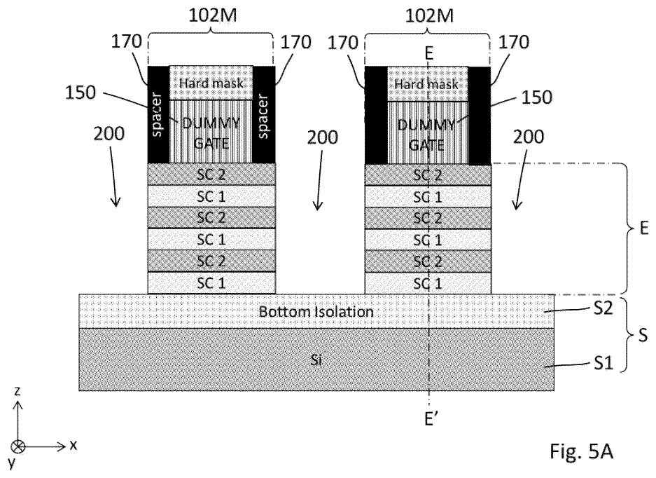

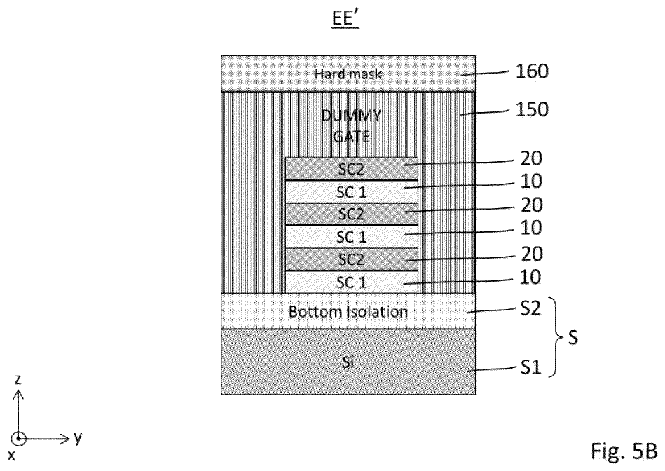

As illustrated in FIGS. 5A, 5B, after formation of the first spacers 170 by deposition/etching, the anisotropic etching along z is extended in order to define second patterns 102M, and second openings 200. The etching is configured to etch the stack E over its entire height, by stopping on the substrate S. It can be done by plasma by using an HBr/O2 etching chemistry.

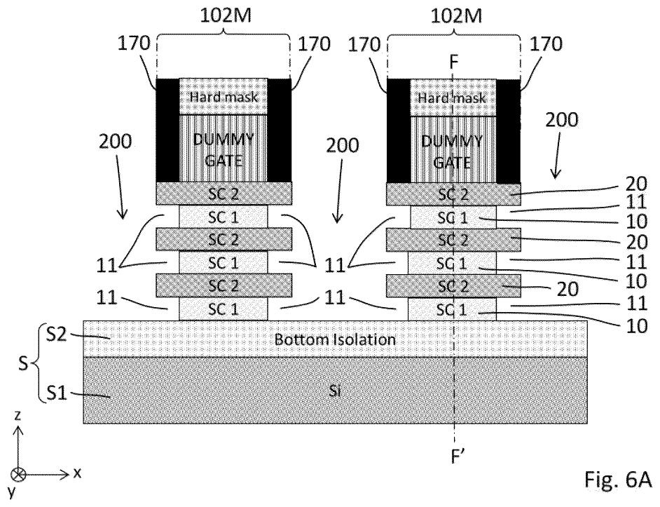

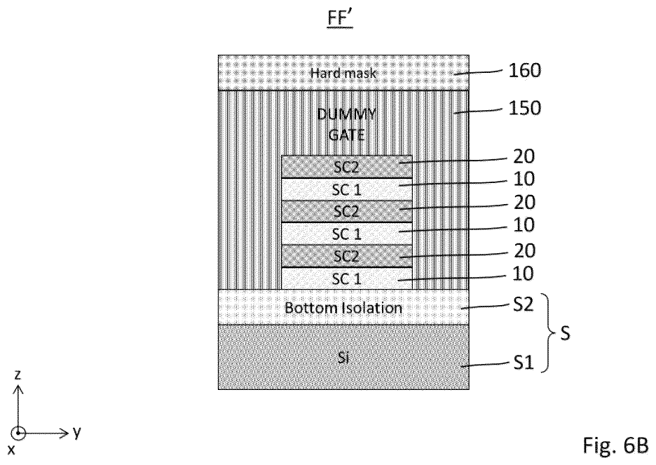

As illustrated in FIGS. 6A, 6B, after formation of the second openings 200, the first layers 10 are partially etched selectively at the second layers 20, at the substrate S and at the first spacers 170. The etching of the first material of the first layers 10 typically has a selectivity S_{10:20} with respect to the second material of the second layers 20, of at least 5:1, preferably at least 10:1. This partial etching aims to form first spaces 11 in vertical alignment with the first spacers 170. This partial etching is typically stopped at the time. It has an isotropic character and can be done wet or dry, from the second openings 200. From this partial etching, central parts of the first layers 10 are preserved under the sacrificial gates 150.

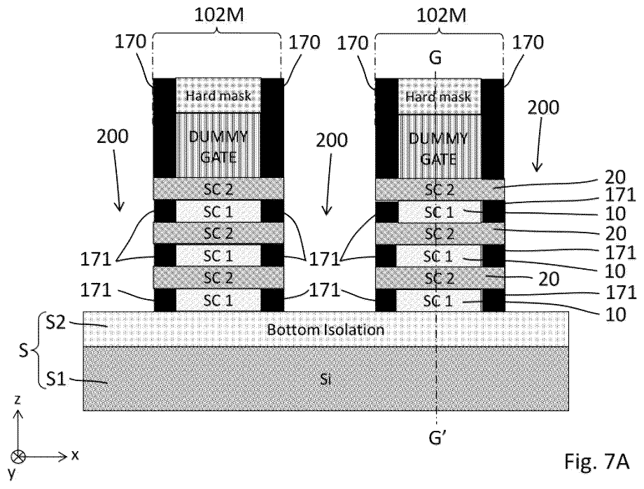

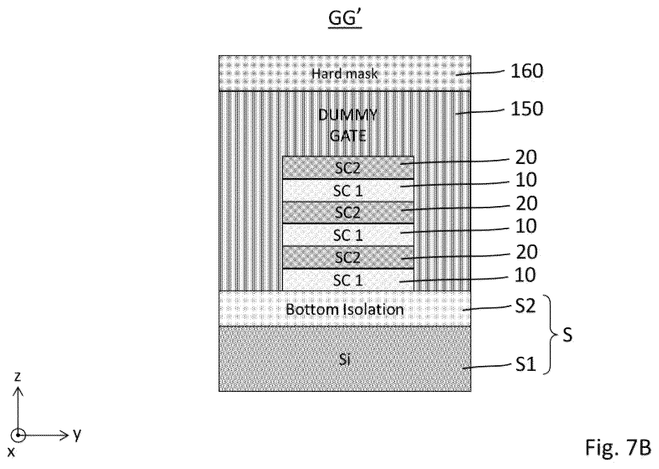

As illustrated in FIGS. 7A, 7B, the first spaces 11 are then filled with a dielectric material, for example, with silicon nitride or with a dielectric with low permittivity, to form internal spacers 171. These “internal” spacers 171 are integrated in the stack E, preferably in vertical alignment with the first spacers 170. They are in contact with the central parts of the first layers 10. The formation of the internal spacers 171 is done typically from the second openings 200.

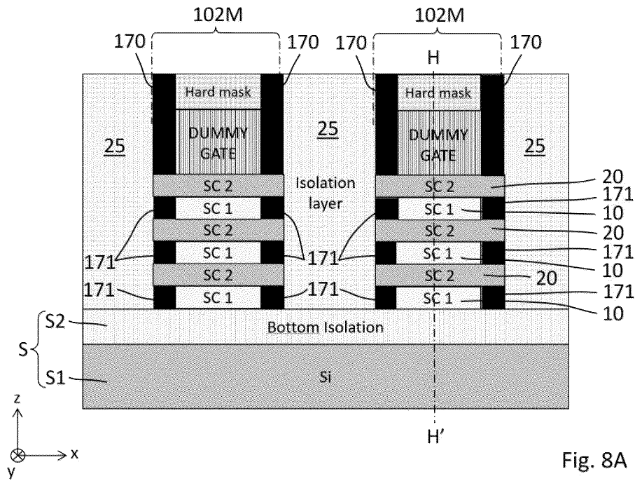

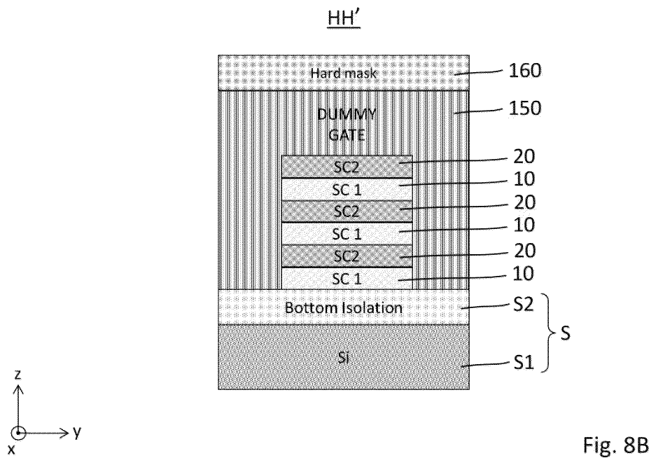

As illustrated in FIGS. 8A, 8B, a holding layer 25, for example, SiO2-based, is deposited on and between the second patterns 102M so as to fill the openings 200. This holding layer 25 is then planarised, typically by chemical-mechanical polishing CMP stopping on the hard masks 160.

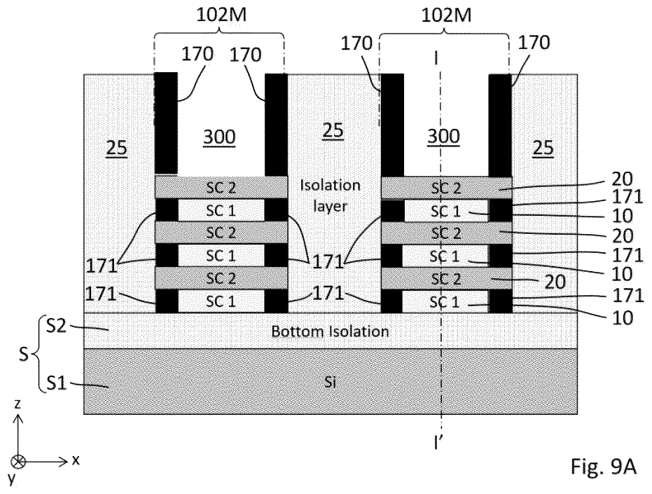

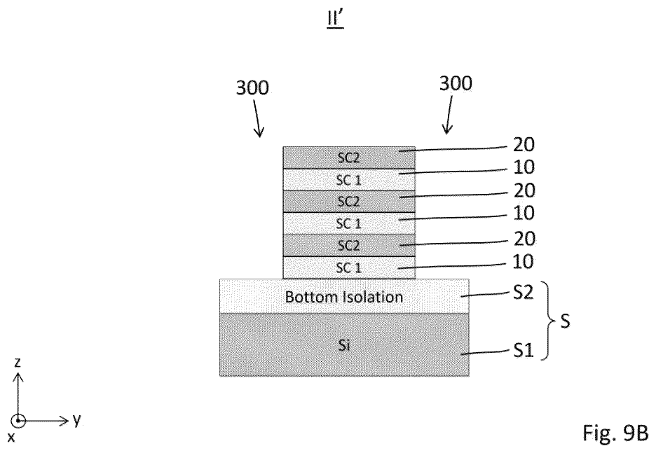

As illustrated in FIGS. 9A, 9B, the hard masks 160 are first removed, then the sacrificial gates 150 are also removed. This removal can be done by wet etching stopping on the thin SiO2-based stop layers or another dielectric. This wet etching typically has a high selectivity with respect to the stop layer and first spacers 170. This wet etching can be based on a TMAH (Tetramethylammonium hydroxide)- or TEAH (Tetraethylammonium hydroxide) ammoniac salt solution. The SiO2-based stop layer is then typically etched wet to expose the upper face of the last layer of the stack E, in this case, a second layer 20. This removal of the sacrificial gates 150 makes it possible to form third openings 300 opening onto the central parts of the first layers 10 (FIG. 9B).

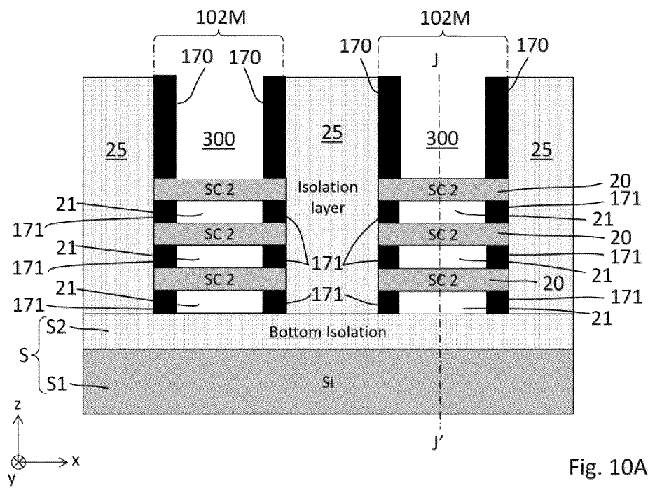

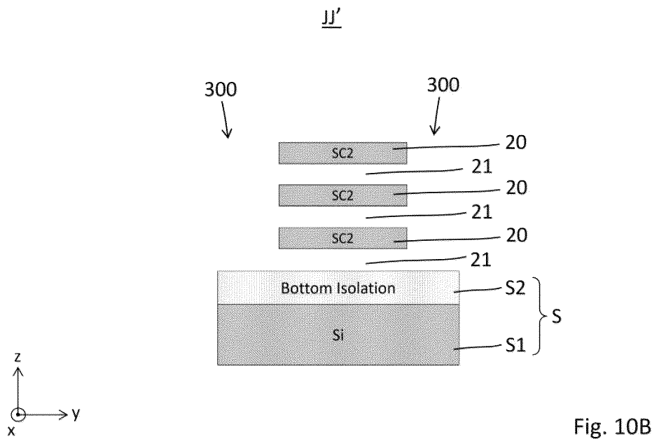

As illustrated in FIGS. 10A, 10B, the central parts of the first layers 10 are then totally etched selectively at the second layers 20, at the internal spacers 171, and at the substrate S from third openings 300. This etching aims to form cavities 21 instead of the central parts of the first layers 10. This total etching can be stopped at the time, possibly after an overetching time aiming to guarantee the total removal of the first material of the first layers 10. This total etching has an isotropic character and can be done wet or dry, from third openings 300. The second layers 20 are maintained by the spacers 170, 171 and by holding layer 25, as illustrated in FIG. 10A. 30

An advantageous step not illustrated in the figures consists of oxidising the exposed parts of the second layers 20 from the third openings 300 and from the cavities 21. This makes it possible to decrease the thickness along z and the lateral dimensions along y of the second material of the second layers 20. After replacement of the second material of the second layers 20 to form the channels of the transistors, this ultimately makes it possible to obtain channels having reduced dimensions along z and along y. The channels of the transistors can thus have dimensions along z and along z of around a few nanometres.

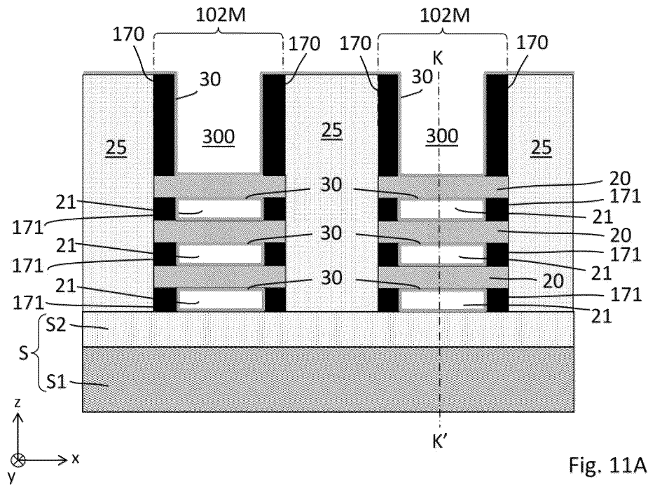

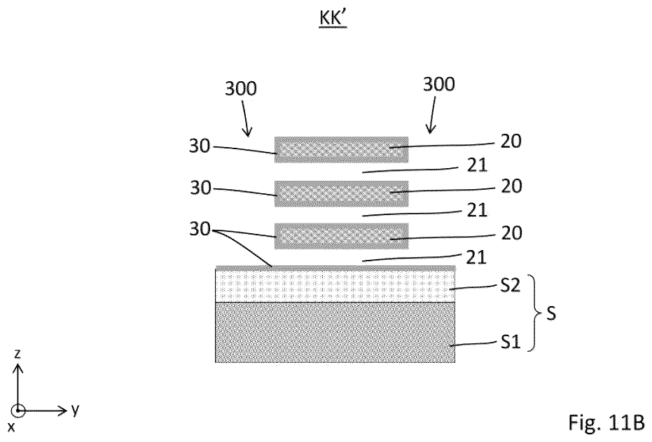

As illustrated in FIGS. 11A, 11B, a dielectric layer 30 is then deposited in the cavities 21 from the openings 300. This dielectric layer 30 is typically based on a material with high permittivity, for example HfO2-based. The dielectric layer 30 is typically intended to form the gate dielectric layer between the channels of the GAA transistors and their gates-all-around. It can be formed by chemical vapour deposition (CVD), by metal organic chemical vapour deposition (MOCVD), or by atomic layer deposition (ALD). It thus covers at least the exposed parts of the second layers 20, and preferably, first spacers 170 and of the internal spacers 171, and the exposed upper face of the substrate S. The dielectric layer 30 typically has a thickness of between 1 nm and 5 nm.

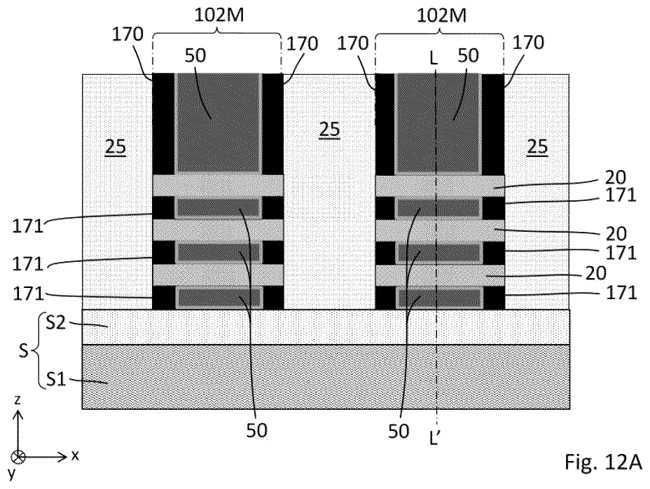

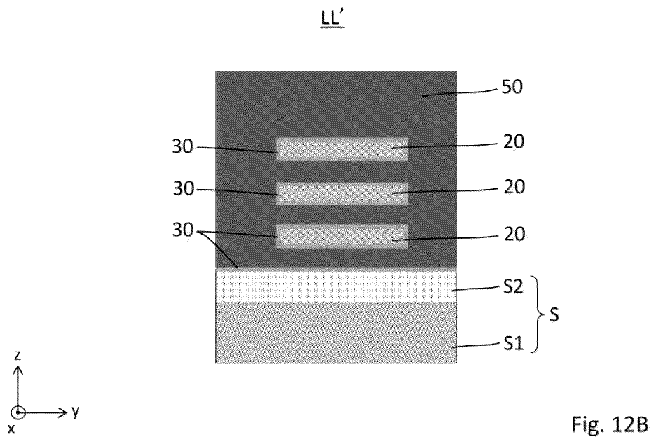

As illustrated in FIGS. 12A, 12B, the third openings 300 and the cavities 21 are then filled with one or more metallic layers 50, for example, TiN-, W-based, in order to form the gates-all-around of the GAA transistors. According to an option, before deposition of the metallic layers 50, a dielectric layer based on a material with high permittivity, for example, HfO2-based, is deposited beforehand in the third openings 300 and the cavities 21. This makes it possible to increase the thickness of the gate dielectric layer between the channels of the GAA transistors and their gates-all-around 50. A chemical-mechanical polishing CMP is typically done in order to remove the excess metal deposited on the patterns 102M.

The steps of the method described above are common to the first and second embodiments of the present invention. The following steps of the method are described below for each of the two embodiments.

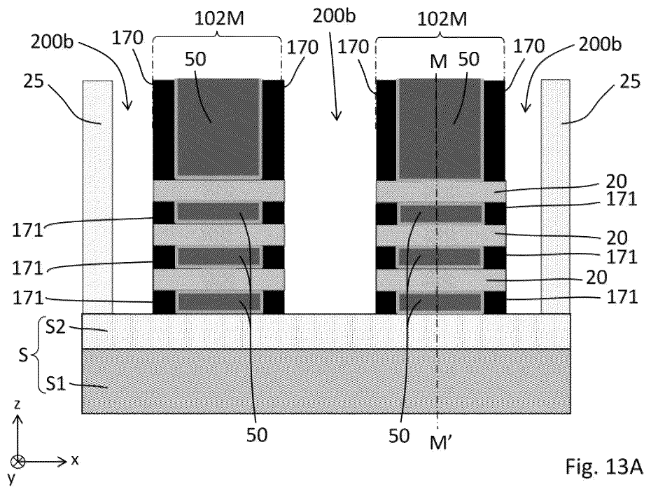

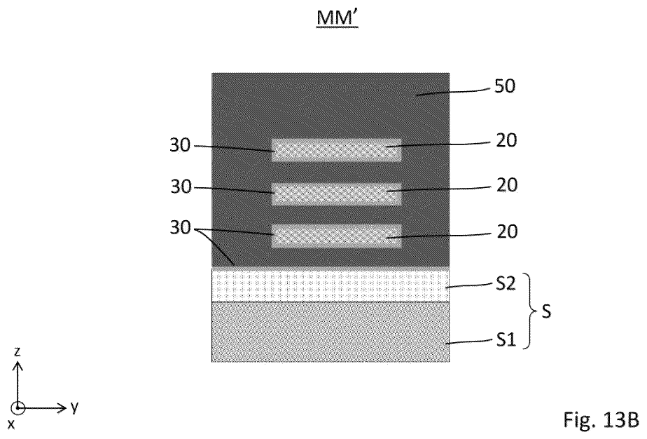

FIGS. 13A, 13B, 14A, 14B, 14C, 15A and 15B schematically illustrate, according to the first embodiment, the continuation of the manufacturing steps of the method enabling the production of the device comprising GAA transistors with stacked channels based on a semi-metallic material.

According to this first embodiment, as illustrated in FIGS. 13A, 13B, the holding layer 25 is opened by etching so as to partially reform the second openings 200b. These second openings 200b define the regions of the source and drain contacts. The two flanks along yz of each pattern 102M are exposed through these second openings 200b.

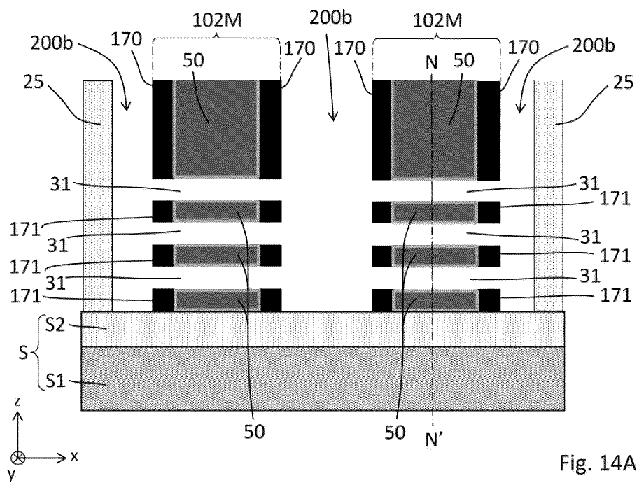

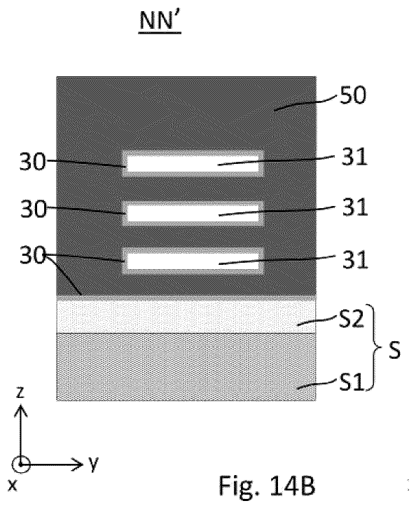

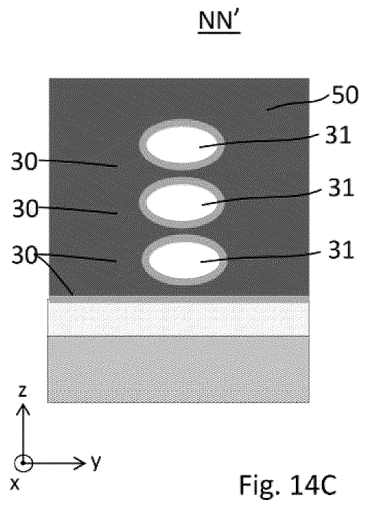

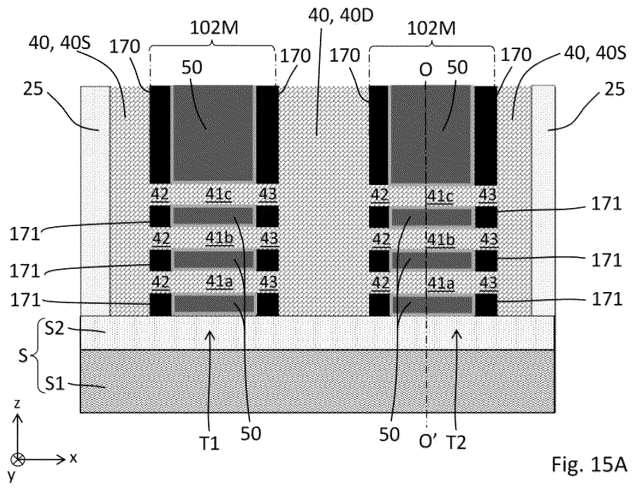

As illustrated in FIGS. 14A, 14B, 14C, the second layers 20 are then totally removed by selective etching with respect to the gate 50, to the dielectric layer 30 and to the spacers 170, 171. This etching can be stopped at the time, possibly after an overetching time aiming to guarantee the total removal of the second material of the second layers 20. This total etching has an isotropic character and can be done wet or dry, from the second openings 200b. From this etching, second spaces 31 are formed instead of the second layers 20. The second openings 200b define the placements of the source and drain contacts. The second spaces 31 define the placements of the channels, of the drains and of the sources.

FIG. 14C illustrates a variant in which the cross-section of the second spaces 31, and subsequently the channels of the transistors, is round or ovoid. Such a rounded shape can be obtained by oxidation of the second layers 20 after formation of the third openings 300 (removal of the sacrificial gate) and of the cavities 21 illustrated in FIG. 10A. More generally, it is understood that this cross-section can adopt one of the following geometric shapes: rectangular, as illustrated in FIG. 14B, elliptic or ovoid, as illustrated in FIG. 14C, circular, square, rectangular with rounded corners or square with rounded corners. Whatever the geometric shape of this cross-section along yz, its dimension along z is preferably between 2 nm and 15 nm.

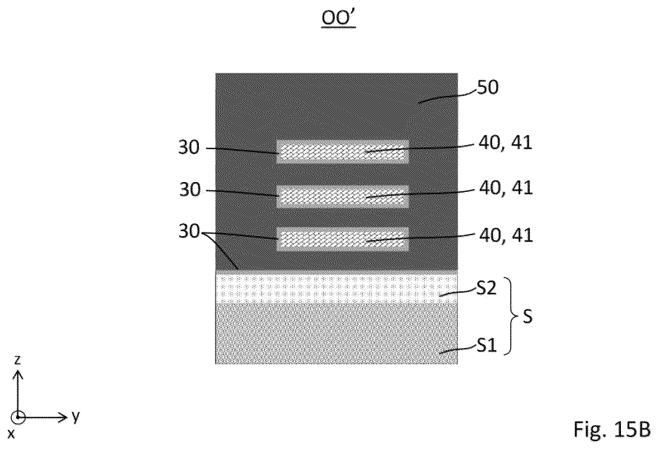

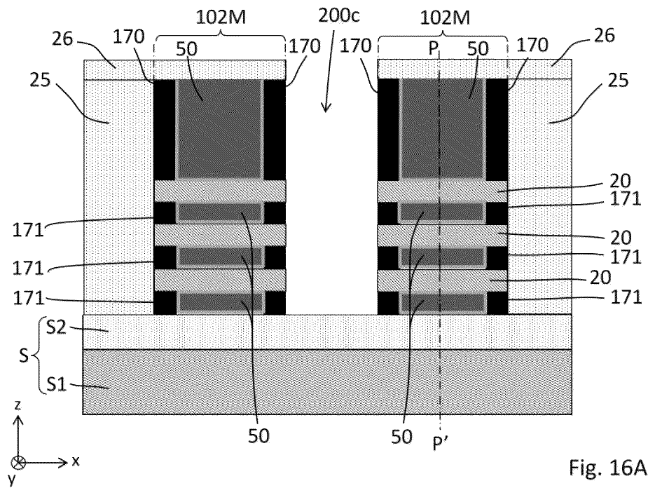

As illustrated in FIGS. 15A, 15B, a layer 40 based on a semi-metallic material is then deposited in the second openings 200b in the second spaces 31. The semi-metallic material can advantageously comprise bismuth. Thus, this semi-metallic material can correspond to bismuth or an alloy comprising bismuth and at least one of the following materials: tin, antimony, arsenic.

The deposition of such a semi-metallic material can be done by MOCVD, ALD or by a combination of these methods, by using, for example, one or more of the following precursor gases: Bis(acetate-O) triphenylbismuth(V) (CH₃CO₂)₂Bi(C₆H₅)₃), triphenylbismuth (Bi(C₆H₅)₃), and Tris(2-methoxyphenyl)bismuthine ((CH₃OC₆H₄)₃Bi). The semi-metallic material can be doped in situ during the deposition. In the case of the bismuth-based semi-metallic material, an example of N-type dopant is the tellurium (Te) element. The in situ doping by the Te element can be done by using one or more of the following precursor gases: anhydrous tellurium tetrabromide (TeBr₄), tellurium tetrachloride (TeCl₄). The concentration of Te in the N-doped bismuth-based metallic material is typically between 10¹⁷ cm⁻³ and 5×10²⁰ cm⁻³.

The deposition of the semi-metallic material is, in this case, configured such that the layer 40 totally fills the second spaces 31 and the second openings 200b. A crystallisation annealing is done after deposition, in order to obtain a crystalline structure for the layer 40. This crystallisation annealing can comprise the implementation of the following steps:
A deposition of at least one covering dielectric material, covering the exposed parts of the semi-metallic material, then
An annealing at a temperature greater than the melting point of the semi-metallic material.

After crystallisation of the semi-metallic material, the layer 40 forms both the channels 41a, 41b, 41c of the GAA transistors T1, T2, the sources 42 and the drains 43 of the GAA transistors T1, T2, and the source and drain contacts 40S, 40D. The channels 41a, 41b, 41c and the sources 42 and the drains 43 advantageously have electric conduction properties of a semiconductor, by constriction of the semi-metallic material of the layer 40. The source and drain contacts 40S, 40D advantageously have electric conduction properties of a metal. Thus, the deposition and the crystallisation annealing of the layer 40 form a plurality of functional elements of the transistors T1, T2, in a minimum amount of steps.

In this method, the semi-metallic material portion forming the channel is not produced beforehand by growth on a metallic substrate, but by deposition of the semi-metallic material in the channel placement.

This method is typically based on the production of a “mould” formed by the channel placements and source and drain contacts, in which the semi-metallic material is then deposited. The deposition of the semi-metallic material in this mould makes it possible to restrict the shape that the semi-metallic material will take after its crystallisation. This also makes it possible avoid the semi-metallic material having rough surfaces.

The semiconductive behaviour of the channels 41a, 41b, 41c is obtained by quantum confinement effect of the charge carriers (electrons). When the semi-metallic material is, for example, bismuth, this quantum confinement effect can be obtained for dimensions of around 15 nm, at ambient temperature. When the semi-metallic material is, for example, tin, this effect can be obtained for dimensions of around 2 nm at ambient temperature.

The crystallisation annealing is preferably implemented at a temperature greater than the melting point of the semi-metallic material. When this semi-metallic material corresponds to bismuth, this annealing is implemented at a temperature greater than 271° C.

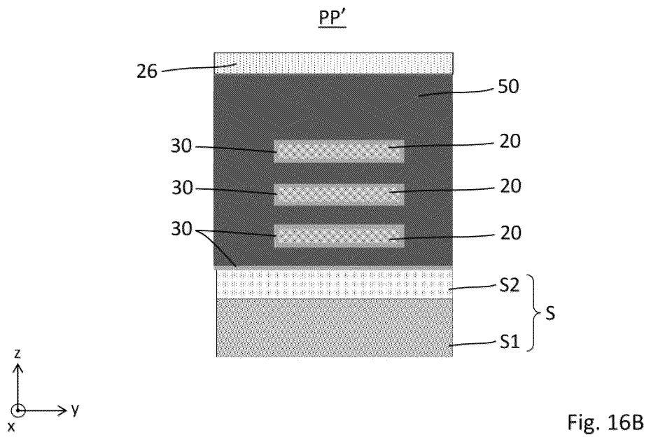

FIGS. 16A, 16B to 20A, 20B schematically illustrate a second embodiment of the method for manufacturing the device comprising GAA transistors with stacked channels based on a semi-metallic material.

According to this second embodiment, as illustrated in FIGS. 16A, 16B, a part of the holding layer 25 and the patterns 102M are masked by deposition of a second dielectric layer 26, in order to only open the drain region located between the two patterns 102M. The second opening(s) 200c correspond, in this case, to the definition of one single type of contact, for example, the drain contacts. One single flank along yz of each pattern 102M is thus exposed through second openings 200c.

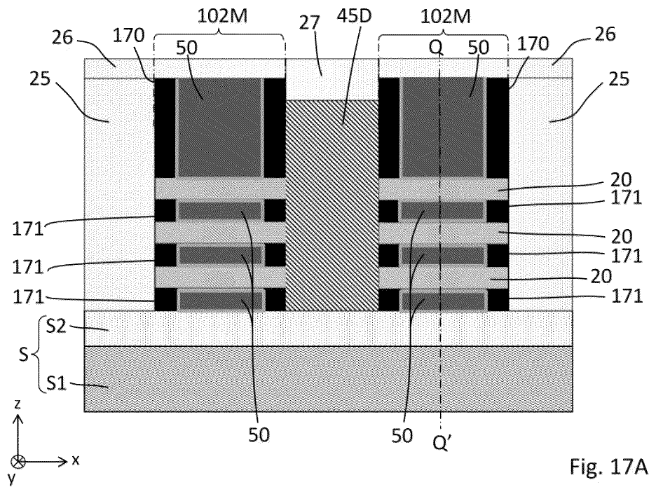

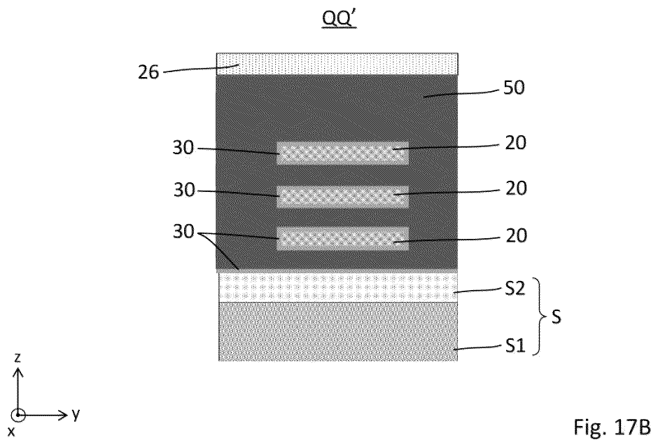

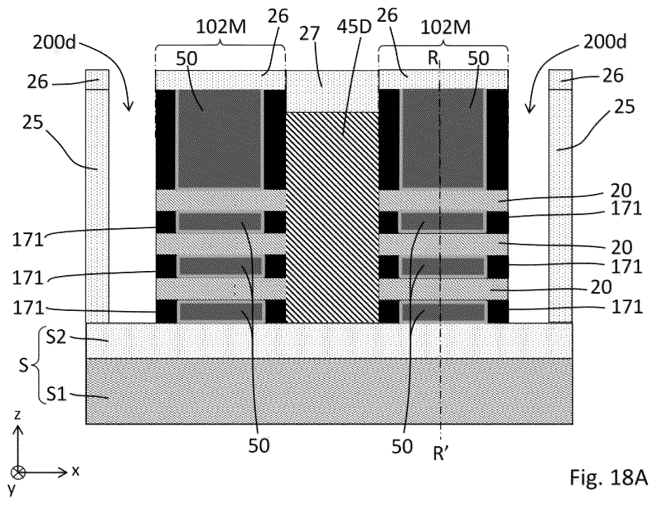

As illustrated in FIGS. 17A, 17B, a layer based on a metallic material is then deposited in the second opening 200c to form the drain contact 45D. The metallic material of the drain contact 45D can conventionally be based on one of the following metals: copper (Cu), cobalt (Co), gold (Au), titanium (Ti), aluminium (Al), nickel (Ni), tungsten (W), titanium nitride (TiN), or other metals. A dielectric stopper 27 is then formed on the drain contact 45D, in order to protect the exposed part of this drain contact 45D.

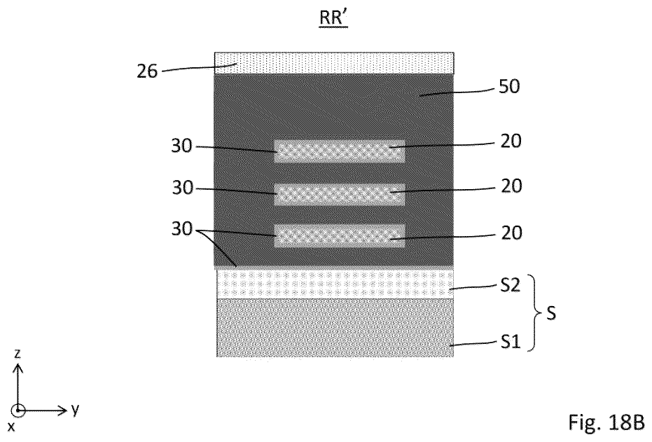

As illustrated in FIGS. 18A, 18B, second openings 200d are then formed in the holding layer 25. The second openings 200d correspond, in this case, to the definition of the other type of contact, for example, the source contacts. The other flank along yz of each pattern 102M is thus exposed through the second openings 200d.

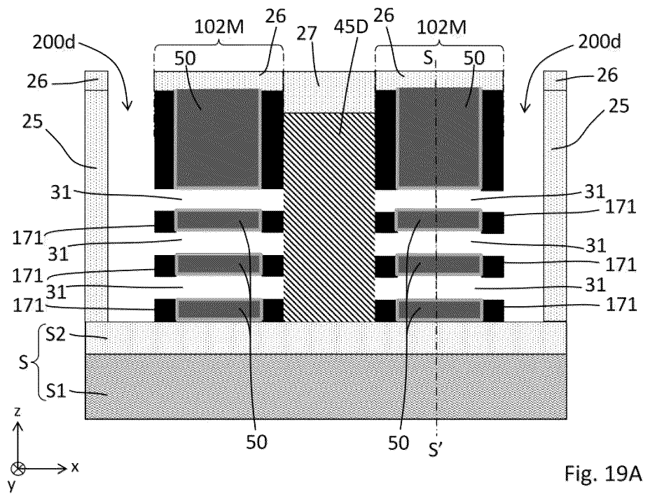

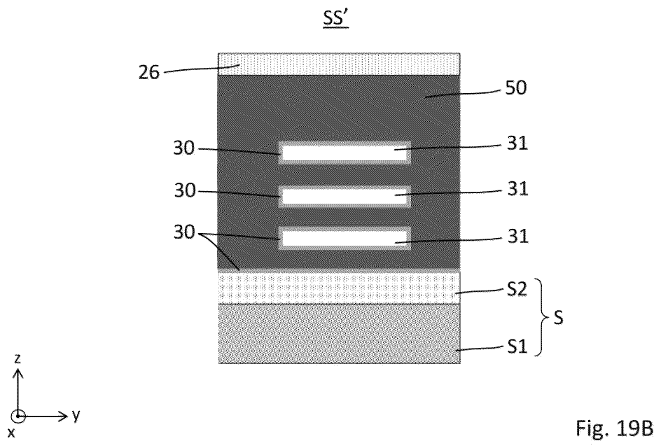

As illustrated in FIGS. 19A, 19B, the second layers 20 are then totally removed by selective etching with respect to the dielectric layer 30, spacers 170, 171, and to the contact 45D. This total etching can be done as above, from the second openings 200d. From this etching, the second spaces 31 are formed instead of the second layers 20.

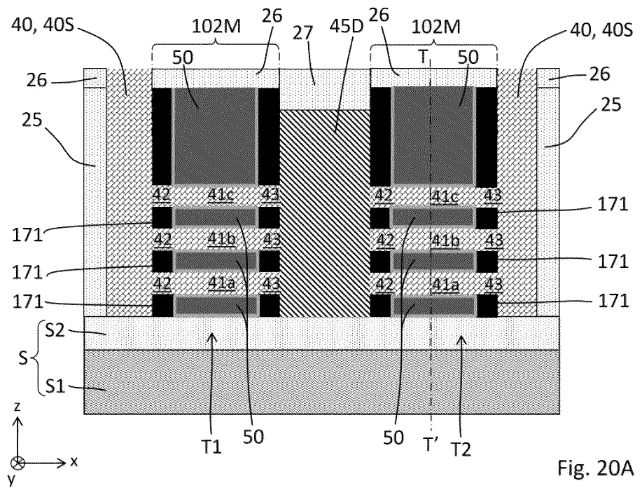

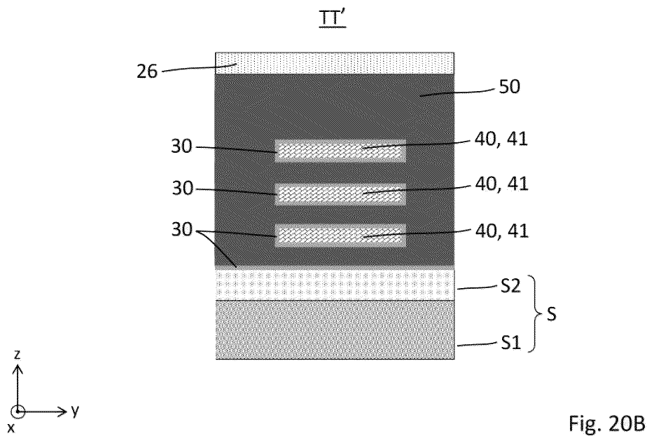

As illustrated in FIGS. 20A, 20B, the layer 40 based on the semi-metallic material is, in this case, formed in the second spaces 31 by growth from the contact 45D. The metal of the contact 45D typically forms a substrate for the epitaxy of the semi-metallic material of the layer 40. As above, a step of crystallising the semi-metallic material is preferably carried out.

The layer 40 forms, as above, the channels 41a, 41b, 41c, the sources 42 and the 20) drains 43 of the GAA transistors T1, T2. The layer 40 forms, in this case, only the source contacts 40S of the GAA transistors T1, T2.

A microelectronic device comprising at least two transistors T1, T2, with channels 41a, 41b, 41c stacked along z and with a gate-all-around 50, is thus advantageously obtained. The channels 41a, 41b, 41c, the sources 42 and the drains 43 are advantageously based on a semi-metallic material. At least one of the source 40S and drain 40D contacts is also based on this semi-metallic material.

The nanometric dimensions along y and/or along z of the channels 41a, 41b, 41c, enabling the semi-metallic material to adopt the properties of a semiconductor. Furthermore, the largest dimensions of the source and drain contacts 40S, 40D, enabling the semi-metallic material to adopt the properties of a metallic material.

In view of the description above, it clearly appears that the proposed method offers a particularly effective solution to form semi-metallic material-based GAA transistors. This solution is further advantageously compatible with standard microelectronic methods. The invention is, however, not limited to the embodiments described above.

1. Microelectronic device comprising at least one transistor (T1, T2) comprising:
a source (42) and a drain (43),
a plurality of channels (41a, 41b, 41c) based on a semi-metallic material, said channels extending along a longitudinal direction (x) between the source (42) and the drain (43), each channel having at least one transverse dimension, taken perpendicularly to the longitudinal direction (x), such that the semi-metallic material has an electric conduction property of a semiconductor material,.
a so-called gate-all-around (50), surrounding at least one of the channels (41a, 41b, 41c), and preferably several channels (41a, 41b, 41c) of the plurality of channels (41a, 41b, 41c),
a gate dielectric layer (30) separating each channel (41a, 41b, 41c) from the gate-all-around (50),
source and drain contacts (40S, 40D) electrically connected respectively to the source (42) and to the drain (43), at least one from among the source and drain contacts (40S, 40D) being based on the semi-metallic material and having dimensions such that the semi-metallic material has an electric conduction property of a metallic material,
spacers (170, 171) on either side of the gate (50), configured to electrically isolate the gate (50) with respect to the source and drain contacts (40S, 40D),
the device being characterised in that the gate-all-around (50) totally surrounds several channels (41a, 41b, 41c) of the plurality of channels (41a, 41b, 41c), in a transverse plane (yz) perpendicular to the longitudinal direction (x), and in that said device rests directly on an isolating layer (S2) of a semiconductor-on-insulator-type substrate(S).

2. Device according to the preceding claim, comprising at least two transistors (T1, T2) disposed along a first so-called horizontal direction (x, y), in which the channels (41a, 41b, 41c) of each transistor (T1, T2) are stacked along a second so-called vertical direction (z), perpendicular to the first direction (x, y).

3. Device according to any one of the preceding claims, wherein the other from among the source and drain contacts (40S, 40D) is based on a metal.

4. Device according to any one of the preceding claims, wherein the semi-metallic material is based on at least one element from among bismuth (Bi), tin (Sn), antimony (Sb) or arsenic (As).

5. Device according to any one of the preceding claims, wherein the source and drain contacts (40S, 40D) are directly in contact with the isolating layer (S2).

6. Device according to any one of the preceding claims, wherein the gate (50) rests on the isolating layer (S2) through the gate dielectric layer (30) only.

7. Device according to any one of claims 1 to 5, wherein at least one channel rests on the isolating layer (S2) either directly, or through the gate dielectric layer (30) only.

8. Method for manufacturing a microelectronic device according to any one of the preceding claims, said method comprising the following steps:
Providing, on a substrate(S) comprising a support layer (S1) and an isolating layer (S2), a stack (E) comprising, along the direction (z), a plurality of first layer (10) made of a first material, alternated with a plurality of second layer (20) made of a second material, the first material and the second material being different from one another and different from the semi-metallic material forming the channels (41a, 41b, 41c),
Forming, in this stack (E), first openings (100) defining first patterns (101M),
Forming a sacrificial gate (150) mounted on the first patterns (101M) and partially in the first openings (100),
Forming, in the first patterns (101M), second openings (200) defining second patterns (102M), such that the second patterns (102M) are transverse to the first patterns (101M),
Forming the gate dielectric layer (30),
Forming the gate spacers (170, 171),
Forming a holding layer (25) in said second openings (200), on exposed flanks of the second patterns (102M),
Removing the sacrificial gate (150) so as to form third openings (300),
Removing totally, from the third openings (300), the first material of the first layers (10) selectively at the second material of the second layers (20), so as to form cavities (21),.
Filling the cavities (21) with a gate material, so as to form the gate-all-around (50),
Removing, at least partially, the holding layer (25) so as to reform at least partially the second openings (200b) exposing flanks of the second layers (20),
Removing totally, from the second openings (200b), the second material of the second layers (20) so as to form second spaces (31),
Depositing a layer (40) based on a semi-metallic material in the second spaces (31) and at least partially in the second openings (200b), so as to simultaneously form:
channels (41a, 41b, 41c) based on the semi-metallic material in vertical alignment with the gate-all-around (50),
at least one from among the source and drain contacts (40S, 40D) based on the semi-metallic material.

9. Manufacturing method according to the preceding claim, wherein the gate-all-around (50) is formed before the deposition of the layer (40) based on the semi-metallic material.

10. Manufacturing method according to any one of claims 8 to 9, wherein the formation of the gate dielectric layer (30) is formed after total removal of the first material from the first layers (11) and before formation of the gate-all-around (50), by deposition of a dielectric layer in the cavities (21) and in the third openings (300), on the exposed parts of the second layers (20).

11. Manufacturing method according to any one of claims 8 to 10, wherein the formation of the spacers (170, 171) and the formation of the gate dielectric layer (30) are done at least partially by one same deposition of a dielectric layer in the cavities (21).

12. Manufacturing method according to any one of claims 8 to 11, wherein the second openings (200c, 200d) are reformed by successively exposing one single flank of the second layers (20), and wherein the deposition of the layer (40) based on the semi-metallic material forms one single contact (40S, 40D) from among the source and drain contacts (40S, 40D).

13. Manufacturing method according to the preceding claim, wherein the other contact from among the source and drain contacts is a metallic contact (45D) formed by deposition of a metallic layer in a part of the second openings (200c).

14. Manufacturing method according to the preceding claim, wherein the deposition of the layer (40) based on the semi-metallic material is done by growth from exposed zones of said metallic contact (45D) through second spaces (31).

15. Manufacturing method according to any one of claims 8 to 14, wherein the second openings (200b) have a constant cross-section along the vertical direction (z), said cross-section being taken in a plane (xy) perpendicular to the vertical direction (z).
